(19) United States
(12) Patent Application Publication
(10) Pub. No.: US 2014/0332713 A1
(43) Pub. Date: Nov. 13, 2014

(54) ETCHING METHOD AND ETCHING LIQUID USED THEREIN

(71) Applicant: FUJIFILM Corporation, Tokyo (JP)

(72) Inventors: Atsushi MIZUTANI, Haibara-gun (JP); Hisamitsu TOMEBA, Haibara-gun (JP); Kazutaka TAKAHASHI, Haibara-gun (JP); Tadashi INABA, Haibara-gun (JP)

(73) Assignee: FUJIFILM Corporation, Tokyo (JP)

(21) Appl. No.: 14/337,301

(22) Filed: Jul. 22, 2014

Related U.S. Application Data
(63) Continuation of application No. PCT/JP2013/051936, filed on Jan. 22, 2013.

(30) Foreign Application Priority Data
Jan. 25, 2012 (JP) 2012-013310

(51) Int. Cl. C23F 1/26; H05K 3/06

(52) U.S. Cl. CPC C23F 1/26; H05K 3/067
USPC 252/79.3; 252/79.1

(57) ABSTRACT

An etching method having the step of: applying an etching liquid to a substrate, the etching liquid containing: a fluorine ion, a nitrogen-containing compound having at least 2 of nitrogen-containing structural units, and water, the etching liquid having a pH of being adjusted to 5 or less; and etching a titanium compound in the substrate.

### CROSS-REFERENCE TO RELATED APPLICATIONS

This application is a Continuation of PCT International Application No. PCT/JP2013/051936 filed on Jan. 22, 2013, which claims priority under 35 U.S.C. §119 (a) to Japanese Patent Application No. 2012-013310 filed on Jan. 25, 2012. Each of the above applications is hereby expressly incorporated by reference, in its entirety, into the present application.

### TECHNICAL FIELD

The present invention relates to an etching method and an etching liquid used therein.

### BACKGROUND ART

Electronic instruments and optical instruments have highly been functionalized increasingly, while having been more miniaturized. In these circumstances, further miniaturization and high integration are in progress relevant to packaging of devices, and their mounting forms are also changing. Specifically, as for the method of jointing chips such as LSI and IC, a wire bonding method has widely been altered to a flip-chip method.

In the flip-chip method, a relay terminal (bonding pad) of a semiconductor chip and a relay terminal of a wiring substrate are electrically connected by a bump electrode, and the both terminals are mechanically jointed. This method is also employed not only in the mounting of the semiconductor chip together with the wiring substrate, but also in the mounting of semiconductor chips, or in the mounting of wiring substrates. Thus, the flip-chip method attains to eliminate the drawing wire that is needed in the conventional wire bonding method. As a result, a mounting area can be reduced and miniaturization of the semiconductor device can be realized.

A solder is usually used for a bump electrode. The solder is formed according to a plating method, a printing method, or a deposition method. On the other hand, a under bump metal film (hereinafter, referred to simply as “a UBM film”) is preliminarily formed on a relay terminal of semiconductor chips. As a result, the bump electrode is formed on the UBM film.

The UBM film may be formed by film formation according to a plating method or a spattering method and then by etching excess of the formed film. Alternatively, a bump is formed after film formation, and then etching may be conducted using the bump as a mask. Ordinarily the UBM film has a single layer structure of titanium, or a laminate structure composed of titanium and other metal(s). Accordingly, a fluorine-based chemical liquid that has a high peel property with respect to titanium is often employed in the etching. On the other hand, the prevention of corrosion with respect to metal(s) other than titanium in the etching step is desired. In view of the above, it is proposed to incorporate various additives into the chemical liquid (for example, Patent Literatures 1 and 2).

### CITATION LIST

### Patent Literatures

Patent Literature 1: JP-A-2005-232559 (“JP-A” means unexamined published Japanese patent application)
Patent Literature 2: WO 2008/098593 Pamphlet

### DISCLOSURE OF INVENTION

### Technical Problem

The present invention addresses to the provision of an etching liquid that is able to remove, with precision at high speed, a titanium compound of a substrate represented by the above-described UBM film, while the etching liquid is able to suppress or inhibit corrosion of aluminum and the like, and to the provision of an etching method using the etching liquid.

### Solution to Problem

According to the present invention, there is provided the following means:

[1] An etching method having the steps of:
applying an etching liquid to a substrate, the etching liquid comprising: a fluorine ion, a nitrogen-containing compound having two or more nitrogen-containing structural units, and water, the etching liquid having a pH of being adjusted to 5 or less; and
etching a titanium compound in the substrate.
   [2] The etching method described in the above item [1], wherein the nitrogen-containing compound has a molecular weight from 300 to 20,000.
   [3] The etching method described in the above item [1] or [2], wherein the nitrogen-containing structural units are selected from the group consisting of the following formulae (a-1) to (a-10):

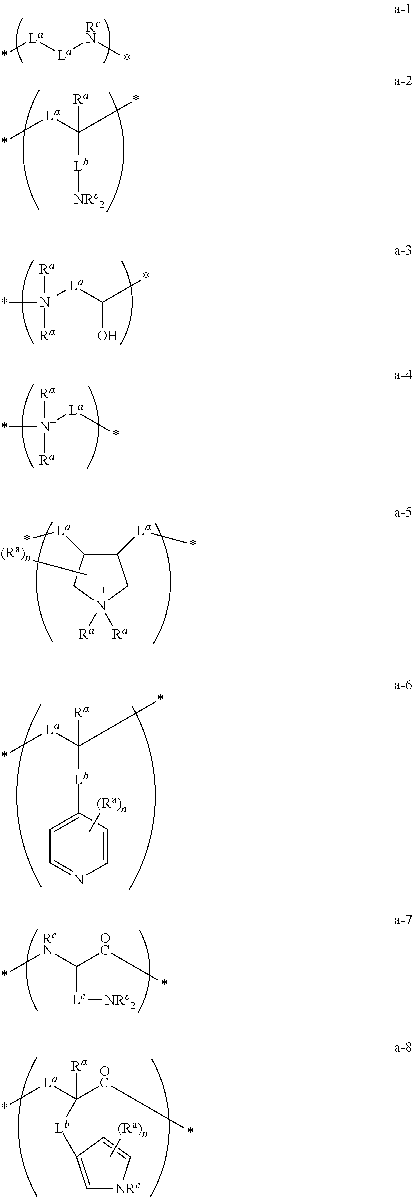

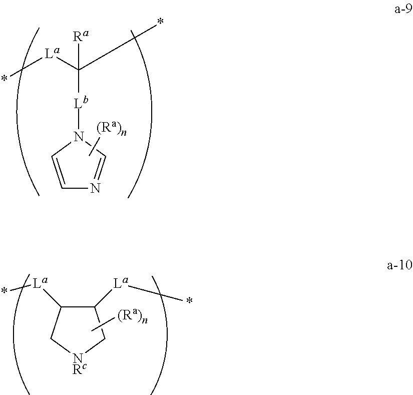

wherein, in the formulae, * represents a binding site; R^{a} represents a hydrogen atom, an alkyl group, an alkenyl group, an aryl group, or a heteroaryl group; L^{a} represents an alkylene group, a carbonyl group, an amino group, an arylene group, a heteroarylene group, or a combination thereof; L^{b} represents a single bond, an alkylene group, a carbonyl group, an amino group, an arylene group, a heteroarylene group, or a combination thereof; L^{c} represents an alkylene group, a carbonyl group, an amino group, an arylene group, a heteroarylene group, or a combination thereof; R^{c} represents a hydrogen atom, or an alkyl group; n represents an integer of 0 or more; when there are more than one R^{a}, R^{c} and L^{a} respectively, respective R^{a}s, R^{c}s and L^{a}s may be the same as or different from each other; and respective R^{a}s and R^{c}s may bind to each other to form a ring.
   [4] The etching method described in the above item [1] or [2], wherein the nitrogen-containing compound is a compound represented by the following formula (b):

R^{c}₂N-[L^{d}-N(R^{c})]ₘ-L^{d}-NR^{c}₂ (b)
wherein L^{d} represents an alkylene group, a carbonyl group, an amino group, an arylene group, a heteroarylene group, or a combination thereof; R^{c} represents a hydrogen atom, or an alkyl group; m represents an integer of 1 or more; respective Ws and L^{d}s may be the same as or different from each other; and respective R^{c}s may bind to each other to form a ring.
   [5] The etching method described in the above item [1] or [2], wherein the nitrogen-containing compound is a polyethyleneimine, a polyallylamine, a polyvinylamine, a polydiallylamine, a polymethyldiallylamine, or a polydimethyldiallylammonium salt.
   [6] The etching method described in any one of the above items [1] to [5], wherein a conjugate acid of the nitrogen-containing compound has a pKa of 5 or more.
   [7] The etching method described in any one of the above items [1] to [6], wherein a ground substance that acts as a supply source of the fluorine ion is one selected from the group consisting of HF, HPF₆, HBF₄, H₂SiF₆ and a salt thereof.
   [8] The etching method described in any one of the above items [1] to [7], wherein the concentration of the fluorine ion is adjusted to be within a range from 0.1% by mass to 10% by mass, and the concentration of the nitrogen-containing compound is adjusted to be within a range from 0.00001% by mass to 10% by mass.
   [9] An etching liquid for applying to a substrate for etching a titanium compound contained in the substrate, the etching liquid has:
a fluorine ion;
a nitrogen-containing compound having two or more nitrogen-containing structural units, and
water,
the etching liquid having a pH of being adjusted to 5 or less.
   [10] The etching liquid described in the above item [9], wherein the nitrogen-containing compound has a molecular weight from 300 to 20,000.
   [11] The etching liquid described in the above item [9] or [10], wherein the nitrogen-containing structural units are selected from the group consisting of the following formulae (a-1) to (a-10):

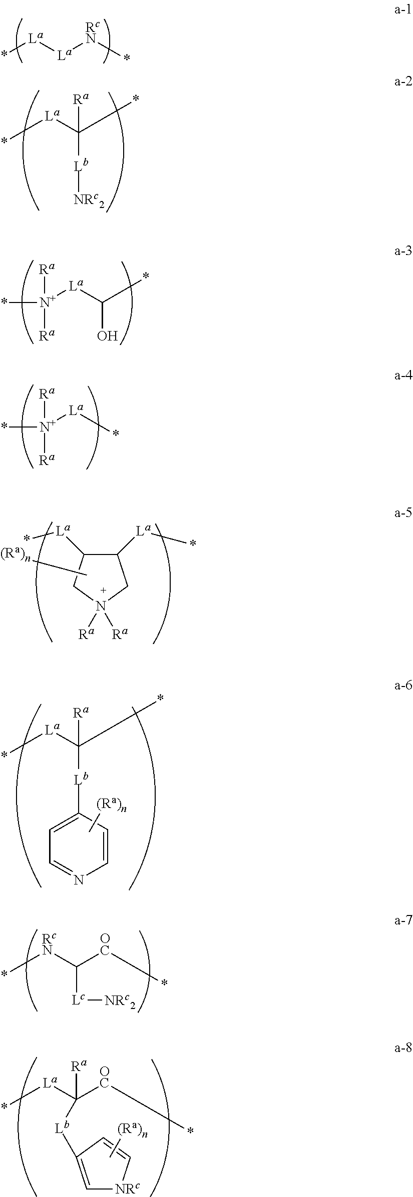

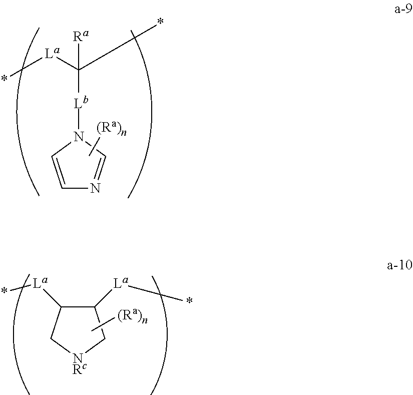

wherein, in the formulae, * represents a binding site; R^{a} represents a hydrogen atom, an alkyl group, an alkenyl group, an aryl group, or a heteroaryl group; L^{a} represents an alkylene group, a carbonyl group, an amino group, an arylene group, a heteroarylene group, or a combination thereof; L^{b} represents a single bond, an alkylene group, a carbonyl group, an amino group, an arylene group, a heteroarylene group, or a combination thereof; L^{c} represents an alkylene group, a carbonyl group, an amino group, an arylene group, a heteroarylene group, or a combination thereof; R^{c} represents a hydrogen atom, or an alkyl group; n represents an integer of 0 or more; when there are more than one R^{a}, R^{c} and L^{a} respectively, respective R^{a}s, R^{c}s and L^{a}s may be the same as or different from each other; and respective R^{a}s and R^{c}s may bind to each other to form a ring.
   [12] The etching liquid described in the above item [9] or [10], wherein the nitrogen-containing compound is a compound represented by the following formula (b):

R^{c}₂N-[L^{d}-N(R^{c})]ₘ-L^{d}-NR^{c}₂ (b)
wherein L^{d} represents an alkylene group, a carbonyl group, an amino group, an arylene group, a heteroarylene group, or a combination thereof; R^{c} represents a hydrogen atom, or an alkyl group; m represents an integer of 1 or more; respective R^{c} s and L^{d}s may be the same as or different from each other; and respective R^{c}s may bind to each other to form a ring.
   [13] The etching liquid described in the above item [9] or [10], wherein the nitrogen-containing compound is a polyethyleneimine, a polyallylamine, a polyvinylamine, a polydiallylamine, a polymethyldiallylamine, or a polydimethyldiallylammonium salt.
   [14] The etching liquid described in any one of the above items [9] to [13], wherein a conjugate acid of the nitrogen-containing compound has a pKa of 5 or more.

### Advantageous Effects of Invention

An etching liquid and an etching method using the etching liquid of the present invention can remove a titanium compound of a substrate represented by the above-described UBM film with precision at high speed, and also makes it possible to suppress or inhibit corrosion of aluminum and the like.

Other and further features and advantages of the invention will appear more fully from the following description, appropriately referring to the accompanying drawing.

### BRIEF DESCRIPTION OF THE DRAWINGS

FIG. 1 is a section view schematically showing an example of processing around a solder bump in a flip-chip method.

### MODE FOR CARRYING OUT THE INVENTION

The etching liquid of the present invention contains a fluorine ion, a specific nitrogen-containing compound, and water, and a pH of the etching liquid has been adjusted to 5 or less. By the etching liquid, an excellent etching property of a titanium compound is achieved, while a good resistance to corrosion of aluminum is exhibited. Although it is not known exactly why these actions are exerted, it is presumed that the specific nitrogen-containing compound takes on a property of cationic material under an acidic environment and a characteristic protective-film is formed on a surface of aluminum. Hereinafter, the present invention is described in detail, based on a preferable example thereof

### [Etching of UBM]

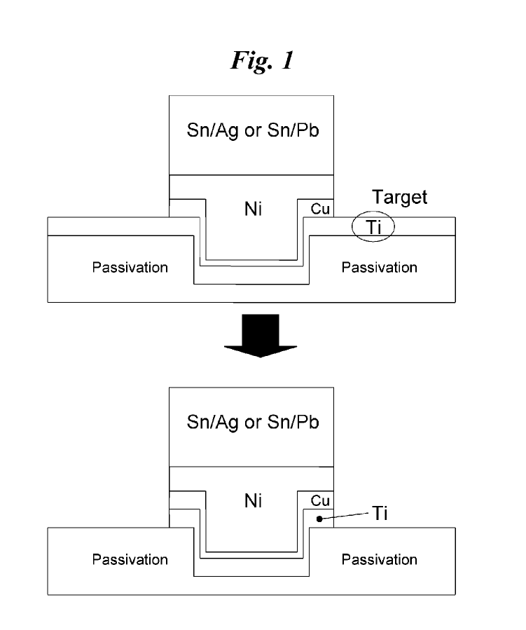

First, an etching form of the UBM film is described before description of the etching liquid. FIG. 1 is a section view schematically showing an etching embodiment of the UBM that is a preferable embodiment of the present invention (a hatching is omitted). In the present embodiment, the UBM film is made of titanium. The target of etching in the present invention is not limited to titanium, but it may be a material containing titanium. For example, such material may be an alloy or composite compound each of which is composed of titanium and other atom(s). Examples of the titanium compound include Ti, Ti—W, and Ti—Cu. Further, the UBM film may be a single layer as shown in the figure, or may be a multiple layer in which two or more layers are laminated. On the other hand, regarding aluminum to be protected, although a metallic aluminum is usually targeted, the target of protection may be an aluminum alloy or an aluminum composite compound.

FIG. 1 (a) shows a state before etching. A titanium layer is disposed such that the titanium layer is spread on a passivation film to cover the passivation film. On the other hand, by applying an etching liquid onto this titanium layer, an exposed titanium portion is removed to make the state shown in FIG. 1 (b). By this process, an electrical connection through titanium in the planar direction is disconnected, which results in the state in which conduction is partially secured in the order of Ti—Cu—Ni—Sn/Ag (SnPb) outward in the thickness direction. Further, a solder electrical connection can be performed via a solder film (Sn/Ag or Sn/Pb) whereby mounting of semiconductors and the like can be performed. Although a thickness of the UBM film is not particularly limited, it is preferably from 1 to 10 μm, and more preferably from 1 to 5 μm, from the viewpoint of securing a sufficient conduction and achieving a suitable etching effect.

At this time, a surface of aluminum that constitutes a circuit wiring and the like is often exposed at another portion of the substrate. When a processing is performed with an etching liquid as described above, the etching liquid inevitably comes at the aluminum surface, and sometimes exerts influence. Especially, a fluorine-based chemical liquid causes serious damage to aluminum (refer to Comparative Examples described below), and corrosion and damage of aluminum may cause a problem in the manufacturing quality of the device. According to the present invention, the corrosion of aluminum can be effectively suppressed or prevented (refer to Examples described below). Further, the present invention, if needed, also enables the etching liquid to exert a good protection property to the solder film (Sn/Ag or Sn/Pb).

### [Etching Liquid]

The etching liquid of the present invention contains a fluorine ion, a specific nitrogen-containing compound, and water. Hereinafter, each of the components is described.

### (Fluorine Ion)

The etching liquid of the present invention contains a fluorine ion. That is, the etching liquid contains a component that generates a fluorine ion in the liquid. A ground substance acting as a supply source of the fluorine ion is not particularly limited. Herein, this is called a fluoric acid compound which means a compound generating in the system a fluorine ion (F⁻), examples of which include fluoric acid (hydrofluoric acid) and salts thereof. Specifically, examples of the fluoric acid compound include fluoric acid, alkali metal fluoride (NaF, KF, and the like), amine hydrofluoride (monoethylamine hydrofluoride, triethylamine trihydrofluoride, and the like), pyridine hydrofluoride, ammonium fluoride, quaternary alkyl ammonium fluoride (tetramethyl ammonium fluoride, tetra n-butyl ammonium fluoride, and the like), H₂SiF₆, HBF₄ and HPF₆, and the fluoric acid compound is preferably selected from fluoric acid, alkali metal fluoride, ammonium fluoride, quaternary alkyl ammonium fluoride, HBF₄, HPF₆ and salts thereof, and in particular, more preferably selected from fluoric acid (HF), HBF₄, HPF₆ and salts thereof.

The fluorine ion is preferably contained at a concentration of 0.1% by mass or more, and more preferably 0.3% by mass or more, with respect to a total mass of the etching liquid. When the concentration is controlled to the above-described lower limit or higher, a high etching rate can be secured. On the other hand, the upper limit of the fluorine ion to be contained is preferably 10% by mass or less, and more preferably 5% by mass or less. When the concentration is controlled to the above-described upper limit or lower, corrosion prevention of aluminum can be achieved, while securing a sufficient etching rate.

### (Specific Nitrogen-Containing Compound)

In the present invention, a nitrogen-containing compound having at least 2 of nitrogen-containing structural units is used. By this, a high corrosion-prevention effect on aluminum can be exerted while fully keeping an etching effect due to fluorine.

For example, the specific nitrogen-containing compound may be a polyamine containing a primary, secondary, tertiary, or quaternary amine functional group, or two or more kinds thereof. A polyelectrolyte may be a cationic surfactant having a hydrophilic (nitrogen-containing) top group and a hydrophobic end group. The polyelectrolyte preferably contains one or plural recurring units containing one selected from the group consisting of amine, amide, imide, imine, alkyl amine, and amino alcohol. The polyelectrolyte may be a polymer or a copolymer containing only the above-described recurring units, or may be a copolymer containing one or a plurality of these recurring units in combination with another (preferably nonionic) recurring unit, for example, ethylene oxide, propylene oxide, styrene, and a mixture thereof. The nonionic recurring unit is present in a positively-charged polyelectrolyte and a steric relationship can be introduced into between complexing recurring units. The number of the nonionic recurring unit existing in the polyelectrolyte is 99% or less (for example, 95%) with respect to the total number of the recurring units. The number of the nonionic recurring unit existing in the polyelectrolyte is preferably 90% or less (for example, 85%) with respect to the total number of the recurring units. Further, the polyelectrolyte may be a copolymer containing the above-described recurring units in combination with other recurring groups containing a functional group incorporating therein, for example, alcohols, phosphonic acids, phosphonates, sulfates, sulfonic acid, sulfonate, phosphates, carboxylic acid, carboxylates and a mixture thereof. The polyelectrolyte may be a homopolymer, a random copolymer, an alternating copolymer, a periodic copolymer, a block copolymer (for example, AB, ABA, ABC and the like), a graft copolymer, or a comb copolymer.

Further, the nitrogen-containing structural unit is preferably a structural unit selected from the following formulae (a-1) to (a-10).

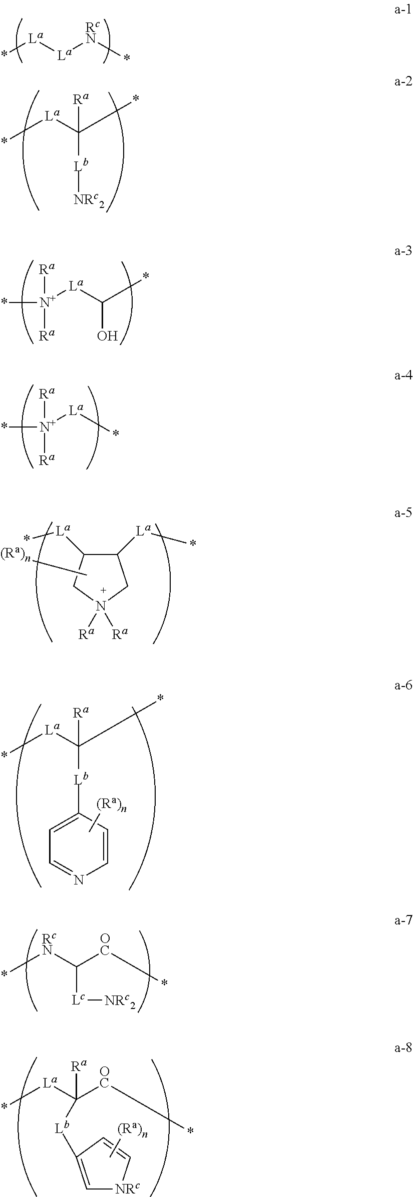

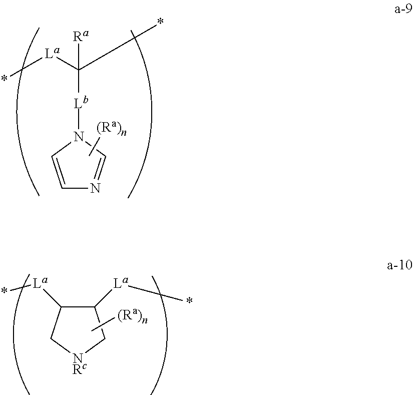

R^{a}

R^{a} represents a hydrogen atom, an alkyl group, an alkenyl group, an aryl group, or a heteroaryl group. Preferable examples thereof include examples of the following substituent T. Among them, R^{a} is preferably a hydrogen atom or a methyl group.

L^{a}

L^{a} represents an alkylene group, a carbonyl group, an amino group, an arylene group, a heteroarylene group, or a combination thereof. Among them, an alkylene group and a carbonyl group are preferable, a methylene group, an ethylene group, a propylene group, and a carbonyl group are more preferable, a methylene group and an ethylene group are furthermore preferable, and a methylene group is particularly preferable.

L^{b}

L^{b} represents a single bond, an alkylene group, a carbonyl group, an amino group, an arylene group, a heteroarylene group, or a combination thereof. Preferable examples as a linking group other than the single bond include the example of L^{a}. Among them, a single bond, a methylene group, and an ethylene group are preferable.

L^{c}

L^{c} represents an alkylene group, a carbonyl group, an amino group (—NR—: R is hydrogen or alkyl group), an arylene group, a heteroarylene group, or a combination thereof. Among them, an alkylene group is preferable and an alkyl group to which an amino group having 2 to 8 carbon atoms may intermediate is preferable.

R^{c}

R^{c} represents a hydrogen atom, or an alkyl group. Preferable examples of the alkyl group include examples of the following substituent T. Among them, R^{c} more preferably represents a hydrogen atom or a methyl group.

n

n represents an integer of 0 or more. The upper limit of n is the number of possible substitution site of each cyclic structure. For example, in formulae (a-5) and (a-6), the number of possible substitution site is 4, in formulae (a-8) and (a-9), the number of possible substitution site is 3.

When there are more than one R^{a}, R^{c} and L^{a} respectively, respective R^{a}s, R^{c}s and L^{a}s may be the same as or different from each other. Respective R^{a}s and R^{c}s may bind to each other to form a ring. Even though the ring formation is not specified in all cases, adjacent substituents or linking groups may bind to each other to form a ring within the extent in which the ring formation does not undermine the effect of the present invention.

Further, the nitrogen-containing compound is preferably a resin represented by the following formula (b).

R^{c}₂N-[L^{d}-N(R^{c})]ₘ-L^{d}-NR^{c}₂ (b)

In formula (b), R^{c} has the same meanings as those of R^{c} described above. m represents an integer of 1 or more, preferably an integer of 2 to 10, and more preferably an integer of 3 to 6.

L^{d} represents an alkylene group, a carbonyl group, an amino group, an arylene group, a heteroarylene group, or a combination thereof. Among them, an alkylene group is preferable, more preferably a methylene group, an ethylene group, a propylene group.

Respective R^{c}s and L^{d}s may be the same as or different from each other. Respective R^{c}s may bind to each other to form a ring.

The nitrogen-containing compound is preferably polyethylene imines, polyallylamines, polyvinylamines, polydiallylamines, polymethyldiallylamines, or polydimethyldiallylammonium salts.

The molecular weight of the nitrogen-containing compound is preferably from 300 to 50,000, more preferably from 300 to 20,000. When the molecular weight is too large, it is not preferable because etching performance of titanium is drastically reduced.

In the present invention, in the case of a low molecular weight compound having a molecular weight of less than 1,000, the molecular weight is defined as a molecular weight which is calculated from the structure identified by various kinds of analysis. In the case of a high molecular weight compound having a molecular weight of 1,000 or more, the molecular weight is defined as a molecular weight which is obtained by the following measurement method.

Unless it is explicitly stated otherwise, the molecular weight and the degree of dispersion are defined as the values obtained by measurement in accordance with a GPC (Gel Permeation Chromatography). The molecular weight is defined as polystyrene-converted mass-average molecular weight. The gel charged into the column used in the GPC method is preferably a gel having an aromatic compound as a repeating unit, and examples thereof include a gel including styrene-divinylbenzene copolymers. The column is preferably used in the form where 2 to 6 columns are connected. Examples of a solvent used include N-methylpyrrolidone, acetonitrile, tetrahydrofuran, formamide (containing lithium bromide as an additive). The measurement is preferably carried out at a flow rate of the solvent in the range of 0.1 to 2 mL/min, and most preferably in the range of 0.5 to 1.5 mL/min. By carrying out the measurement within these ranges, there is no occurrence of loading in an apparatus, and thus, the measurement can be carried out further efficiently. The measurement temperature is 40° C. unless specified. A column and a carrier to be used can be properly selected, according to the property of a polymer compound to be measured.

In the specific nitrogen-containing compound, pKa of the conjugate acid thereof is preferably 5 or more, more preferably 6 or more. Although the upper limit thereof is not particularly limited, it is practically 14 or less.

Herein, the acid dissociation constant pKa refers to an acid dissociation constant pKa in an aqueous solution, for example, any of those listed in Kagaku Binran (Chemical Handbook) (II) (Revised 4th Edition, 1993, edited by The Chemical Society of Japan, published by Maruzen Co., Ltd.). The lower the value of acid dissociation constant, the greater the acid strength. For example, the acid dissociation constant pKa in an aqueous solution can be actually measured through the determination of the acid dissociation constant at 25° C. using an infinitely diluted aqueous solution. The acid dissociation constant can be obtained from pH dependency of electrical conductivity of an aqueous solution, as described in the 5th edition Jikken Kagaku Koza (edited by The Chemical Society of Japan, published by MARUZEN Co., Ltd.), Vol. 20-1, p. 65. Further, in the case where the nitrogen-containing compound is a polymer, the acid dissociation constant also can be defined by the pKa of a nitrogen-containing monomer compound which constitutes a basis of a recurring structure of the polymer. In this case, when two or more kinds of nitrogen-containing monomers are copolymerized, the acid dissociation constant can be represented by the pKa of a nitrogen-containing monomer from which a recurring unit of the polymer is originated, the recurring unit being contained most in the polymer.

The concentration of the specific nitrogen-containing compound is preferably 0.00001 mass %, more preferably 0.0001 mass %, to the total mass of the etching liquid. When the concentration is controlled to the above-described lower limit or more, a sufficient protection performance of aluminum can be realized. On the other hand, the upper limit of the nitrogen-containing compound to be contained is preferably 10% by mass or less, and more preferably 5% by mass or less. When the concentration is controlled to the above-described upper limit or less, a good etching rate can be secured without excessively interfering with the effectiveness of etching due to the fluorine ion.

Hereinafter, specific examples of the specific nitrogen-containing compound are described. However, the present invention is not construed by being limited thereto.

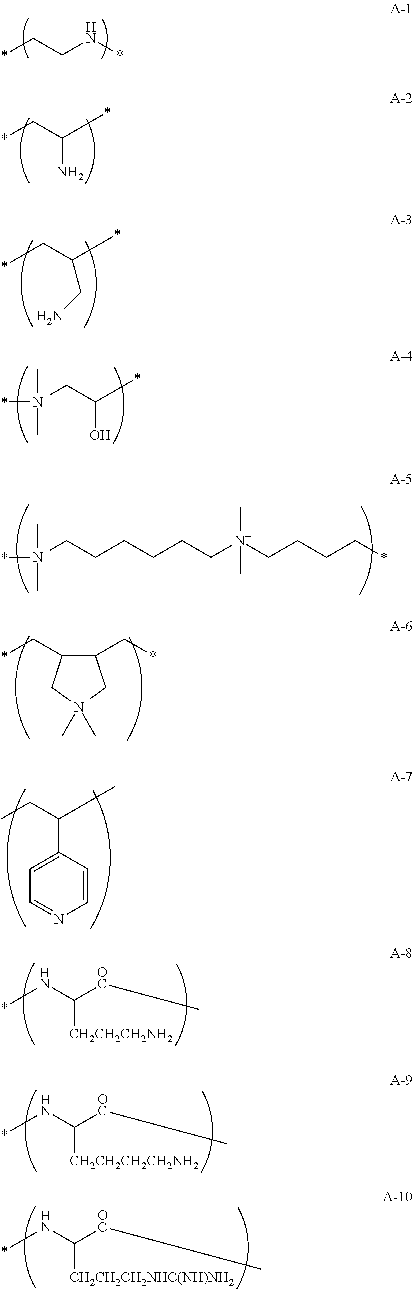

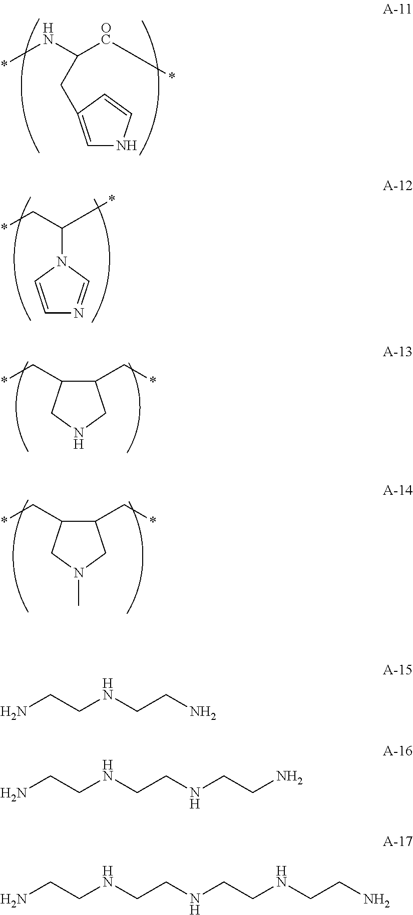

A-1 Polyethylene imine
A-2 Polyvinylamine
A-3 Polyallylamine
A-4 Dimethylamine epihydrine-based polymer
A-5 Polyhexadimethrine
A-6 Polydimethyldiallyl ammonium salt
A-7 Poly(4-vinylpyridine)
A-8 Polyornithine
A-9 Polylysine
A-10 Polyarginine
A-11 Polyhistidine
A-12 Polyvinylimidazole
A-13 Polydiallylamine
A-14 Polymethyldiallylamine
A-15 Diethylenetriamine
A-16 Tri ethyl enetetramine
A-17 Tetraethylenepentamine
A-18 Pentaethylenehexamine

In the present specification, a showing of the compound is used to mean not only the compound itself, but also a salt or ion thereof and the like. Further, the showing of the compound is also used to mean incorporation of derivatives modified by a predefined configuration to an extent necessary to obtain a desired effect.

Further in the present specification, a substituent (including a linking group) in which substitution or non-substitution is not explicitly stated means that the substituent may have any substituent. This is also applied to the compound in which substitution or non-substitution is not explicitly stated. Examples of preferable substituents include the following substituent T.

The substituent T includes the following substituents.

The substituents include an alkyl group (preferably an alkyl group having 1 to 20 carbon atom(s), for example, methyl, ethyl, isopropyl, t-butyl, pentyl, heptyl, 1-ethylpentyl, benzyl, 2-ethoxyethyl, and 1-carboxymethyl), an alkenyl group (preferably an alkenyl group having 2 to 20 carbon atoms, for example, vinyl, allyl, and oleyl), an alkynyl group (preferably an alkynyl group having 2 to 20 carbon atoms, for example, ethynyl, butadiynyl, and phenylethynyl), a cycloalkyl group (preferably a cycloalkyl group having 3 to 20 carbon atoms, for example, cyclopropyl, cyclopentyl, cyclohexyl, and 4-methylcyclohexyl), an aryl group (preferably an aryl group having 6 to 26 carbon atoms, for example, phenyl, 1-naphthyl, 4-methoxyphenyl, 2-chlorophenyl, and 3-methylphenyl), a heterocyclic group (preferably a heterocyclic group having 2 to 20 carbon atoms, and preferably a heterocyclic group having 2 to 20 carbon atoms, 5- or 6-membered ring having at least one oxygen atom, nitrogen atom, or sulfur atom, for example, 2-pyridyl, 4-pyridyl, 2-imidazolyl, 2-benzimidazolyl, 2-thiazolyl, and 2-oxazolyl), an alkoxy group (preferably an alkoxy group having 1 to 20 carbon atom(s), for example, methoxy, ethoxy, isopropyloxy, and benzyloxy), an aryloxy group (preferably an aryloxy group having 6 to 26 carbon atoms, for example, phenoxy, 1-naphthyloxy, 3-methylphenoxy, and 4-methoxyphenoxy), an alkoxycarbonyl group (preferably an alkoxycarbonyl group having 2 to 20 carbon atoms, for example, ethoxycarbonyl and 2-ethylhexyloxycarbonyl), an amino group (preferably an amino group having 0 to 20 carbon atom(s), an alkyl amino group, an aryl amino group, for example, amino, N,N-dimethylamino, N,N-diethylamino, N-ethylamino, and anilino), a sulfamoyl group (preferably a sulfamoyl group having 0 to 20 carbon atom(s), for example, N,N-dimethylsulfamoyl, and N-phenylsulfamoyl), an acyloxy group (preferably an acyloxy group having 1 to 20 carbon atom(s), for example, acethyloxy and benzoyloxy), a carbamoyl group (preferably a carbamoyl group having 1 to 20 carbon atom(s), for example, N,N-dimethylcarbamoyl and N-phenylcarbamoyl), an acylamino group (preferably an acylamino group having 1 to 20 carbon atom(s), for example, acetylamino and benzoylamino), a sulfonamide group (preferably a sulfonamide group having 0 to 20 carbon atom(s) for example, methanesulfonamide, benzenesulfonamide, N-methylmethanesulfonamide, N-ethylbenzenesulfonamide), a hydroxy group, a cyano group, and a halogen atom (for example, a fluorine atom, a chlorine atom, a bromine atom, and an iodine atom). Among them, an alkyl group, an alkenyl group, an aryl group, a heterocyclic group, an alkoxy group, an aryloxy group, an alkoxycarbonyl group, an amino group, an acylamino group, a cyano group, and a halogen atom are more preferable. An alkyl group, an alkenyl group, a heterocyclic group, an alkoxy group, an alkoxycarbonyl group, an amino group, an acylamino group, and a cyano group are particularly preferable.

In the case where a compound, a substituent, a linking group, and the like include an alkyl group, an alkylene group, an alkenyl group, an alkenylene group, and the like, these may be a straight chain, or branched, and may be substituted or not substituted as described above. Further, when an aryl group, a heterocyclic group, and the like are include therein, these may be a single ring or a condensed ring, and similarly these may be substituted or not substituted.

### (Water)

The etching liquid of the present invention contains water, and may be a water-based liquid composition containing an aqueous medium as a medium. The aqueous medium refers to an aqueous solution in which water and a water-soluble solute have been dissolved. Examples of the solute include alcohols and a salt of inorganic compounds other than the above-described essential components. However, when the solute is used, it is preferable that the amount thereof is limited to the extent in which a desired effect is exerted. Further, the water-based liquid composition refers to a composition in which an aqueous medium is contained as a main medium. Preferably, more than half of the medium excluding the solid content is water, more preferably the content of water is from 55% by mass to 100% by mass, and especially preferably the content of water is from 60% by mass to 100% by mass, with respect to the medium.

In view of application to use of the semiconductor production which is a particularly-favorable intended use of the present invention, it goes without saying that basically, clean water is preferable. Specifically, it is preferable that a metal content which can influence a semiconductor; halogen anions (Cl⁻, Br⁻ and the like) other than fluorine contained in the present invention; and other impurities are as little as possible. As a method for obtaining such water, an ion exchange method and the like are exemplified.

In the present specification, the term “substrate”, that can be a target of etching, may be typically a circuit board for mounting a device. Besides, the substrate may be the one for mounting optical devices like a light-emitting diode (LED). The substrate may be or may not be a plate-shape, and may be a part of a structure mounting a devise, LED, or the like. In the case where a UBM film structure is formed in the semiconductor device, LED, or the like, the substrate of this device or the substrate in the production step can be recognized as the term of substrate. A substrate in production may be named as a semiconductor substrate product.

The top and bottom of the substrate may not be defined in particular. In the present specification, based on the graphic illustration, the side of the solder (Sn/Ag or Sn/Pb) is defined as the upside (top) direction, while the side of the passivation film that acts as a substrate is defined as the downside (bottom) direction.

(pH)

The etching liquid of the present invention is acidic, and the etching liquid has been adjusted to a pH of 5 or less. The adjustment may be conducted by adjusting amounts of the above-described essential components to be added. However, the adjustment may be conducted by relation to optional components, and the above range may be set using another pH controlling agent, as long as it does not undermine the effect of the present invention. The pH of the etching liquid is 5 or less, and preferably 3 or less. When the pH is controlled to the above-described upper limit or less, a sufficient etching rate can be obtained. Although there is no particular lower limit to the pH, it is practical that the pH is 0 or more.

In the present invention, the pH is a value obtained by measurement at room temperature (25° C.) using F-51 (trade name, manufactured by HORIBA, Ltd.), unless it is explicitly stated otherwise. Alternatively, the pH may be a value obtained by measurement in accordance with the JIS Z8802 measurement method. The time of measurement is not particularly limited. In the case where the pH tends to change with time, the pH is defined as a value obtained by measurement directly (within 5 minutes) after preparation of a liquid. At this time, an initial value may be identified by estimating temporal change using a calibration curve.

### (Other Component)

pH Controlling Agent

As the pH controlling agent, various organic acids, inorganic acids, organic alkalis, and inorganic alkalis may be appropriately used. Examples of the organic acids include carboxylic acids such as acetic acid, and sulfonic acids such as methane sulfonic acid. Examples of the inorganic acids include hydrochloric acid, sulfuric acid and nitric acid. Examples of the organic alkalis include tetraalkyl ammonium hydroxide such as tetraalkyl ammonium hydroxide. Examples of the inorganic alkalis include sodium hydroxide, potassium hydroxide, NH₄OH and NH₄F. Other than these pH controlling agent also can be appropriately used.

### [Kit]

The etching liquid of the present invention may be prepared in a form of a kit in which two or more liquids are put in separate containers. For example, a first liquid containing a fluorine ion and a second liquid containing the above-described specific nitrogen-containing compound are combined to constitute a kit, and both liquids may be mixed when they are used. At this time, it is preferable that each liquid has been adjusted so that the pH after mixing is 5 or less. However, a pH controlling agent may be separately added. A preferable range of content and the like of each liquid after mixing is the same as described in the above-described section of Etching liquid.

### [Concentration]

The etching liquid of the present invention may be concentrated to be stored. To do this is preferable because the volume of the preservation liquid can be reduced whereby the storage space can be reduced. Although the concentration method is not particularly limited, a method of preparing a high concentration of liquid at an initial stage of the preparation is exemplified. Although the magnification ratio of concentration is not particularly limited, a setting form of from twice to 50 times of the concentration, at which the liquid is used, is exemplified. The concentration of the concentrated liquid is preferably from 0.2 to 60% by mass in terms of the above-described concentration of fluorine ion. According to the etching liquid relating to a preferable embodiment of the present invention, a good performance can be maintained even when the liquid is used by diluting it again after concentration.

### [Etching Method]

Although the etching apparatus used in the present invention is not particularly limited, a single wafer type or batch type apparatus may be used. The single wafer type is a method of etching each wafer. One embodiment of the single wafer type is a method of etching by spreading an etching liquid entirely over the surface of a wafer using a spin coater. The batch type is a method of etching at once from several sheets to several ten sheets of wafer. One embodiment of the batch type is a method of etching by soaking two or more sheets of wafer in a tank filled with an etching liquid.

The liquid temperature of the etching liquid, the spray discharge rate of the etching liquid, and the rotation number of wafer of the spin coater are used by selecting appropriate values through selection of the wafer as an etching target.

The etching conditions in the present embodiment are not particularly limited, but the etching method may be a spray-type (single wafer type) etching or a batch-type (immersion type) etching. In the spray-type etching, semiconductor substrates are transported or rotated in the predetermined direction, and an etching liquid is sprayed in a space between them to put the etching liquid on the semiconductor substrate. According to the necessity, while rotating a substrate by using a spin coater, the etching liquid may be sprayed to the substrate. On the other hand, in the batch-type etching, a semiconductor substrate is immersed in a liquid bath constituted of an etching liquid to put the etching liquid on the semiconductor substrate. It is preferable for these etching methods to be appropriately used and selectively depending on a structure, a material, and the like of the device.

An environmental temperature is described below. In the case of the spray-type, the temperature of the spraying interspace for etching is set to a range of preferably from 10 to 100° C., and more preferably from 15 to 80° C. On the other hand, the temperature of the etching liquid is preferably set to a range from 15 to 80° C., and more preferably from 20 to 70° C. It is preferable to set the temperature to the above-described lower limit or more because an adequate etching rate with respect to a metal layer can be ensured by the temperature. It is preferable to set the temperature to the above-described upper limit or less because selectivity of etching can be ensured by the temperature. The supply rate of the etching liquid is not particularly limited, but is set to a range of preferably from 0.05 to 5 L/minute, and more preferably from 0.1 to 0.3 L/minute. It is preferable to set the supply rate to the above-described lower limit or more because uniformity of etching in a plane can be ensured by the supply rate. It is preferable to set the supply rate to the above-described upper limit or less because stable selectivity at the time of continuous processing can be ensured by the supply rate. When the semiconductor substrate is rotated, it is preferable from the same view point as the above to rotate the semiconductor substrate at a rate from 50 to 1,000 rpm, even though the rate may depend on the size or the like of the semiconductor substrate.

In the case of the batch-type, the temperature of the liquid bath is set to a range of preferably from 15 to 80° C., and more preferably from 20 to 70° C. It is preferable to set the temperature to the above-described lower limit or more because an adequate etching rate can be ensured by the temperature. It is preferable to set the temperature to the above-described upper limit or less because selectivity of etching can be ensured by the temperature. The immersion time of the semiconductor substrate is not particularly limited, but the immersion time is set to a range of preferable from 0.5 to 30 minutes, and more preferably from 1 to 10 minute(s). It is preferable to set the immersion time to the above-described lower limit or more because uniformity of etching in a plane can be ensured by the immersion time. It is preferable to set the immersion time to the above-described upper limit or less because stable selectivity at the time of continuous processing can be ensured by the immersion time.

Hereinafter, descriptions are given about step requirements relating to a method of producing a processed product of the substrate that is preferable in the present invention.

(1) The production method includes a step of providing a substrate having a UBM film containing a titanium compound (in the present specification, the expression “providing” has meanings including not only production and preparation using raw materials, but also procurement by purchase and the like), and a step of etching at least a part of the titanium compound that constitutes the UBM film by applying the above-described specific etching liquid onto the substrate.
(2) The step of providing the substrate includes a step of forming the UBM film above the upper side of a passivation film and a step of forming the solder film above the upper side of the UBM film, and a titanium compound at the portion where the solder film is not disposed in the etching step is removed.

The present invention will be described in more detail based on the following examples, but the invention is not intended to be limited thereto.

### EXAMPLES

### Example 1 and Comparative Example 1

The etching liquids (test liquids) designed to have components and compositions (% by mass) shown in the following Table 1 were prepared. The residue was water (ion exchange water).

A Ti film of 0.5 μm, an Al film of 0.5 μm and a SnAg film of 0.5 μm were formed on a silicon wafer of 200 mm. This was cut into pieces of 2 cm×2 cm to use it as test samples.

The test sample was immersed in each of test liquids at 25° C. for 1 minute, and the etching rate was calculated by measuring a film thickness before and after immersion. The immersion was performed in a 200 mL beaker filled with a 100 mL of a chemical liquid, while stirring at 500 rpm. This processing was conducted by stiffing with a stirrer in a size of 7Φ×20 (mm). After immersion, a rinse processing was performed with running water of 2 L/min. Then, the test sample was dried by nitrogen blow.

Corrosivity of Al was evaluated by observing color after immersion with naked eyes.
A: No change of color
B: Somewhat white turbidity appeared.
C: White turbidity appeared.
D: Color unevenness was confirmed.

### [Film Thickness Measuring Method]

A film thickness measuring method in accordance with a 4-turminal method was employed. As a measuring apparatus, VR-120S (trade name) manufactured by Hitachi Kokusai Denki Engineering Co., Ltd. was used.

TABLE 1

| | Evaluation of chemical liquid | | | | | |
|---|---|---|---|---|---|---|
| | Fluoric acid | Concentration | | Concentration | Controlling | |
| | compound | (mass %) | Additive species | (mass %) | agent | pH |
| 101 | HF | 1.0 | Polyhexadimethrine, Mw 6,000 | 0.01 | — | 2.1 |
| 102 | HF | 2.0 | Poly(4-vinylpyridine), Mw 2,000 | 0.02 | TMAH | 2.8 |
| 103 | HPF₆ | 1.5 | Polyvinylimidazole, Mw 6,000 | 0.02 | — | 1.8 |
| 104 | HF | 0.5 | Dimethylamine epihydrine-based polymer, Mw 5,000 | 0.02 | NH₄F | 2.5 |
| 105 | HF | 0.6 | Polyvinylamine, Mw 5,000 | 0.1 | — | 1.9 |
| 106 | HBF₄ | 2.0 | Polyethyleneimine, Mw 300 | 0.05 | NH₄OH | 2.0 |
| 107 | HF | 1.2 | Polydimethyldiallylamine, Mw 3,000 | 0.009 | — | 1.8 |
| 108 | HF | 1.5 | Polyhistidine, Mw 5,000 | 0.005 | KOH | 2.7 |
| 109 | HF | 2.0 | Polyallylamine, Mw 3,000 | 0.01 | — | 1.8 |
| 110 | HF | 1.6 | Polyarginine, Mw 7,000 | 0.02 | H₂SO₄ | 1.0 |
| 111 | HF | 0.9 | Polymethyldiallylamine, Mw 1,000 | 0.07 | — | 2.0 |
| 112 | HF | 1.0 | Polyallylamine, Mw 2,000 | 0.01 | HCl | 1.4 |
| 113 | HF | 1.2 | Polyethyleneimine, Mw 10,000 | 0.005 | — | 1.8 |
| 114 | HF | 0.5 | Polyethyleneimine, Mw 600 | 0.01 | — | 1.9 |
| 115 | HF | 1.0 | Polyallylamine, Mw 3,000 | 2 | H₂SO₄ | 2.0 |
| 116 | HF | 0.8 | Polyallylamine, Mw 2,000 | 0.0001 | — | 1.8 |
| 117 | HF | 3.0 | Polylysine, Mw 4,000 | 0.05 | — | 2.0 |
| 118 | HF | 1.5 | Polyallylamine, Mw 25,000 | 0.001 | — | 1.8 |
| 119 | HF | 1.0 | Polyornithine, Mw 2,000 | 0.02 | — | 1.9 |
| 120 | HF | 0.8 | Diethylenetriamine | 0.9 | HCl | 2.0 |
| 121 | HF | 1.2 | Triethylenetetramine | 0.8 | H₂SO₄ | 1.8 |
| 122 | HF | 0.4 | Tetraethylenepentamine | 1 | H₂SO₄ | 2.5 |
| 123 | HF | 0.6 | Polyallylamine, Mw 10,000 | 0.5 | NH₄F | 4.5 |
| 124 | H₂SiF₆ | 0.5 | Polyvinylamine, Mw 15,000 | 0.05 | — | 2.0 |
| 125 | HF | 0.7 | Pentaethylenehexamine | 2 | CH₃SO₃H | 1.1 |
| C11 | HF | 0.5 | — | — | — | 1.8 |
| C12 | HF | 0.5 | Polyallylamine, Mw 3,000 | 0.01 | NH₄OH | 6.0 |
| C13 | HF | 1.0 | 1,2,3-benzotriazole | 1 | — | 1.9 |
| C14 | HF | 1.0 | 1,2,3-benzotriazole | 20 | — | 5.0 |

Evaluation result

| | | | Color of | |
|---|---|---|---|---|
| | Ti ER (nm/min.) | A1 ER (nm/min.) | A1 | SnAg ER (nm/min.) |
| 101 | 125 | 25 | A | 53 |
| 102 | 160 | 22 | A | 53 |
| 103 | 140 | 23 | A | 54 |
| 104 | 120 | 21 | A | 55 |
| 105 | 100 | 10 | A | 51 |
| 106 | 160 | 15 | A | 45 |
| 107 | 135 | 10 | A | 52 |
| 108 | 140 | 40 | B | 56 |
| 109 | 160 | 17 | A | 50 |
| 110 | 140 | 45 | B | 58 |
| 111 | 100 | 13 | A | 51 |
| 112 | 135 | 14 | A | 53 |
| 113 | 120 | 12 | A | 42 |
| 114 | 130 | 11 | A | 40 |
| 115 | 80 | 11 | A | 61 |
| 116 | 140 | 67 | C | 58 |
| 117 | 180 | 47 | B | 56 |
| 118 | 160 | 55 | B | 57 |
| 119 | 140 | 38 | B | 55 |
| 120 | 130 | 70 | C | 60 |
| 121 | 140 | 75 | C | 55 |
| 122 | 120 | 58 | C | 59 |
| 123 | 75 | 15 | A | 54 |
| 124 | 120 | 45 | C | 55 |
| 125 | 110 | 50 | C | 58 |
| C11 | 120 | 120 | D | 75 |
| C12 | 0 | 10 | A | 50 |
| C13 | 120 | 100 | D | 65 |
| C14 | 10 | 10 | A | 10 |

Notes of Table
Ti ER: Etching rate of Ti
A1 ER: Etching rate of A1
SnAg ER: Etching rate of Sn_{0.95}Ag_{0.05}
TMAH: tetramethylammonium hydroxide
Mw: weight-average molecular weight

From the results shown above, it is seen that the etching liquid of the present invention exhibits a good protection performance for aluminum or a solder material (SnAg), while maintaining a sufficient etching rate for titanium.

### Example 2

Next, concentrated liquids were prepared such that the solutes in the etching liquid 101 shown above were condensed 10-fold, 20-fold, 30-fold, and 40-fold, respectively. These liquids were stored at room temperature for 2 months. After that, the liquids were diluted until 1-fold to conduct the same etching test as described above. From the test results, it was found that excessive performance degradation was not recognized even after concentrated storage and a good etching performance was maintained.

Having described our invention as related to the present embodiments, it is our intention that the invention not be limited by any of the details of the description, unless otherwise specified, but rather be construed broadly within its spirit and scope as set out in the accompanying claims.

1. An etching method comprising the steps of:
applying an etching liquid to a substrate, the etching liquid comprising: a fluorine ion, a nitrogen-containing compound having two or more nitrogen-containing structural units, and water, the etching liquid having a pH of being adjusted to 5 or less; and
etching a titanium compound in the substrate.

2. The etching method according to claim 1, wherein the nitrogen-containing compound has a molecular weight from 300 to 20,000.

3. The etching method according to claim 1, wherein the nitrogen-containing structural units are selected from the group consisting of the following formulae (a-1) to (a-10): 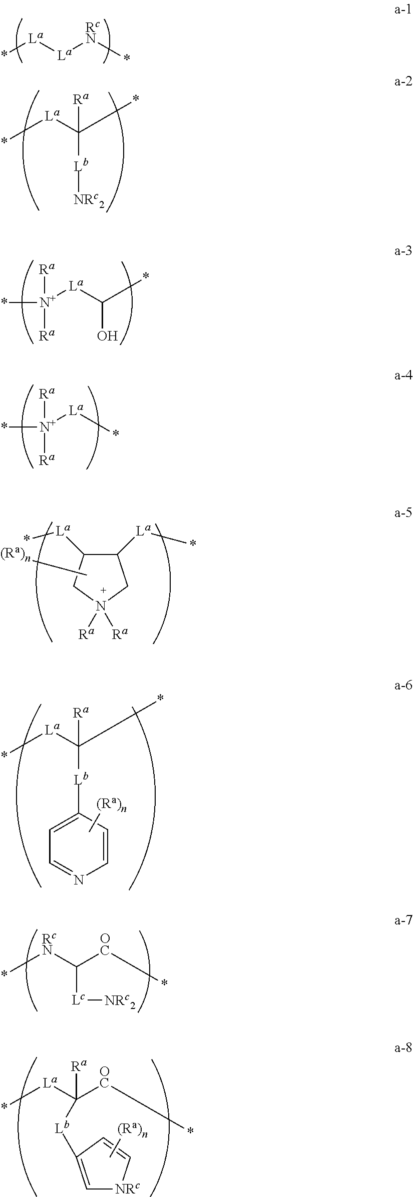 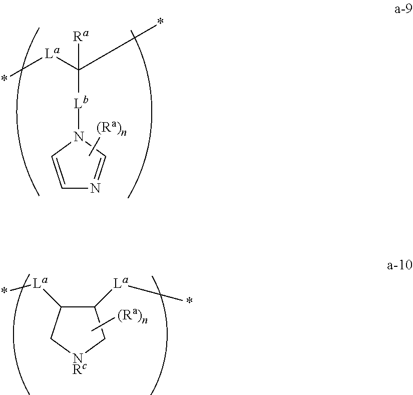
wherein, in the formulae, IV represents a hydrogen atom, an alkyl group, an alkenyl group, an aryl group, or a heteroaryl group; L^{a} represents an alkylene group, a carbonyl group, an amino group, an arylene group, a heteroarylene group, or a combination thereof; L^{b} represents a single bond, an alkylene group, a carbonyl group, an amino group, an arylene group, a heteroarylene group, or a combination thereof; Le represents an alkylene group, a carbonyl group, an amino group, an arylene group, a heteroarylene group, or a combination thereof; R^{c} represents a hydrogen atom, or an alkyl group; n represents an integer of 0 or more; when there are more than one R^{a}, R^{c} and L^{a} respectively, respective R^{a}s, R^{c}s and L^{a}s may be the same as or different from each other; and respective R^{a}s and R^{c}s may bind to each other to form a ring.

4. The etching method according to claim 1, wherein the nitrogen-containing compound is a compound represented by the following formula (b):
R^{c}₂N-[L^{d}-N(R^{c})]ₘ-L^{d}-NR^{c}₂ (b)
wherein L^{d} represents an alkylene group, a carbonyl group, an amino group, an arylene group, a heteroarylene group, or a combination thereof; R^{c} represents a hydrogen atom, or an alkyl group; m represents an integer of 1 or more; respective R^{c} s and L^{d}s may be the same as or different from each other; and respective R^{c}s may bind to each other to form a ring.

5. The etching method according to claim 1, wherein the nitrogen-containing compound is a polyethyleneimine, a polyallylamine, a polyvinylamine, a polydiallylamine, a polymethyldiallylamine, or a polydimethyldiallylammonium salt.

6. The etching method according to claim 1, wherein a conjugate acid of the nitrogen-containing compound has a pKa of 5 or more.

7. The etching method according to claim 1, wherein a ground substance that acts as a supply source of the fluorine ion is one selected from the group consisting of HF, HPF₆, HBF₄, H₂SiF₆ and a salt thereof.

8. The etching method according to claim 1, wherein the concentration of the fluorine ion is adjusted to be within a range from 0.1% by mass to 10% by mass, and the concentration of the nitrogen-containing compound is adjusted to be within a range from 0.00001% by mass to 10% by mass.

9. An etching liquid for applying to a substrate for etching a titanium compound contained in the substrate, the etching liquid comprises:
a fluorine ion;
a nitrogen-containing compound having two or more nitrogen-containing structural units, and
water,
the etching liquid having a pH of being adjusted to 5 or less.

10. The etching liquid according to claim 9, wherein the nitrogen-containing compound has a molecular weight from 300 to 20,000.

11. The etching liquid according to claim 9, wherein the nitrogen-containing structural units are selected from the group consisting of the following formulae (a-1) to (a-10): 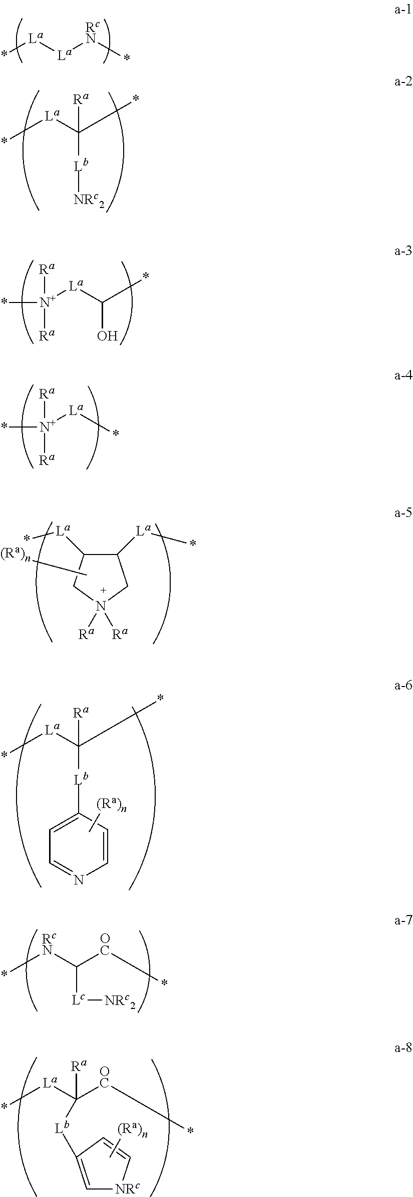 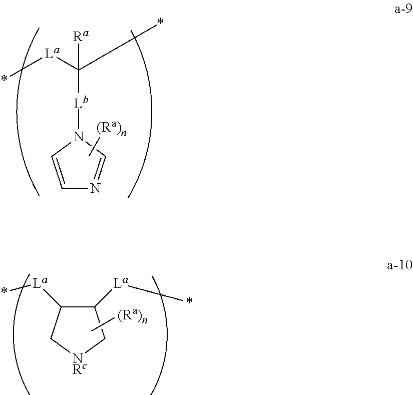
wherein, in the formulae, R^{a} represents a hydrogen atom, an alkyl group, an alkenyl group, an aryl group, or a heteroaryl group; L^{a} represents an alkylene group, a carbonyl group, an amino group, an arylene group, a heteroarylene group, or a combination thereof; L^{b} represents a single bond, an alkylene group, a carbonyl group, an amino group, an arylene group, a heteroarylene group, or a combination thereof; L^{c} represents an alkylene group, a carbonyl group, an amino group, an arylene group, a heteroarylene group, or a combination thereof; R^{c} represents a hydrogen atom, or an alkyl group; n represents an integer of 0 or more; when there are more than one R^{a}, R^{c} and L^{a} respectively, respective R^{a}s, R^{c}s and L^{a}s may be the same as or different from each other; and respective R^{a}s and R^{c}s may bind to each other to form a ring.

12. The etching liquid according to claim 9, wherein the nitrogen-containing compound is a compound represented by the following formula (b):
R^{c}₂N-[L^{d}-N(R^{c})]ₘ-L^{d}-NR^{c}₂ (b)
wherein L^{d} represents an alkylene group, a carbonyl group, an amino group, an arylene group, a heteroarylene group, or a combination thereof; R^{c} represents a hydrogen atom, or an alkyl group; m represents an integer of 1 or more; respective R^{c} s and L^{d}s may be the same as or different from each other; and respective R^{c}s may bind to each other to form a ring.

13. The etching liquid according to claim 9, wherein the nitrogen-containing compound is a polyethyleneimine, a polyallylamine, a polyvinylamine, a polydiallylamine, a polymethyldiallylamine, or a polydimethyldiallylammonium salt.

14. The etching liquid according to claim 9, wherein a conjugate acid of the nitrogen-containing compound has a pKa of 5 or more.
